(19) United States
(12) Patent Application Publication
(10) Pub. No.: US 2008/0290349 A1
(43) Pub. Date: Nov. 27, 2008

(54) Compound semiconductor wafer, light emitting diode and manufacturing method thereof

(75) Inventor: Ken Takahashi, Mito (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: HITACHI CABLE, LTD., Tokyo (JP)

(21) Appl. No.: 12/149,090

(22) Filed: Apr. 25, 2008

(30) Foreign Application Priority Data
May 24, 2007 (JP) 2007-137765

(51) Int. Cl. H01L 33/00; H01L 21/00

(52) U.S. Cl. 257/79; 438/46; 257/E33.001; 257/E21.001

(57) ABSTRACT

A light emitting diode includes a compound semiconductor crystal layer (2) including an emission layer (22) and a conductive substrate (6) bonded to the crystal layer (2) through a metallic layer (5). The metallic layer (2) includes a first metallic layer (51) formed on one principal surface of the compound semiconductor crystal layer (2), a second metallic layer (53) formed on one principal surface of the conductive substrate (6), and a metallic microparticle layer (52) composed of metallic microparticles which are 1 nm to 100 nm in average diameter and bonded to each other between the first metallic layer (51) and the second metallic layer (53).

The present application is based on Japanese patent application No. 2007-137765 filed on May 24, 2007, the entire contents of which are incorporated herein by reference.

### BACKGROUND OF THE INVENTION

1. Field of the Invention

The present invention relates to a compound semiconductor wafer and a light emitting diode that are structured such that a compound semiconductor crystalline layer and a conductive substrate are joined through a metallic layer. Also, the present invention relates to a manufacturing method of the light emitting diode.

2. Description of the Related Art

Light emitting diodes (LEDs) using AlGaInP-based semiconductors, AlGaAs-based semiconductors and AlGaInN-based semiconductors as an emission layer thereof are used as various information devices, home electronics devices, industry devices and indication light sources for an automobile or the like, a market of the LEDs is growing more than ever. In particular, in LEDs using AlGaInP-based semiconductors, on a standpoint of luminance increase, structures such as a compound semiconductor crystalline layer and a conductive substrate consisting of Si or the like which are joined through a metallic layer are actively studied, for example, in JP-A-H10-12917 and JP-A-2001-339100.

FIG. 3 is a cross-sectional structure view showing a conventional LED.

The LED is structured such that a compound semiconductor crystal layer 2 and a conductive substrate 6 are bonded through a metallic layer 5. The compound semiconductor crystal layer 2 mainly comprises a first cladding layer 21, an active layer 22, and a second cladding layer 23. A transparent film 3 and a partial ohmic electrode 4 are formed on the bonding portion side-surface of the compound semiconductor crystal layer 2. A first electrode 1 is formed on the light-emitting-side surface of the compound semiconductor crystal layer 2, and a second electrode 7 is formed on the surface of the conductive substrate 6 opposite the bonding portion side. The first electrode 1 is in ohmic contact with the compound semiconductor crystal layer 2, and the second electrode 7 is in ohmic contact with the conductive substrate 6. The metallic layer 5 is composed of a single layer or multilayer, and generally can function as a bonding layer for bonding the compound semiconductor crystal layer 2 to the conductive substrate 6, as an adhesion layer for adhering the transparent film 3 to the partial ohmic electrode 4, as a light reflection layer, as a layer for suppressing the diffusion of constituent elements of the partial ohmic electrode 4 and the conductive substrate 6 into the interface of the bonding portion, and as a layer in ohmic contact with the conductive substrate 6.

The operation of the LED as shown in FIG. 3 will be described simply below.

When a voltage is applied to turn on electricity between the first electrode 1 and the second electrode 7, a light emission occurs in an active layer 22. A light emitted in the direction of the first cladding layer 21 is externally radiated from the LED through its light emitting surface. On the other hand, a light emitted in the direction of the second cladding layer 23 is reflected on the metallic layer 5 to be externally radiated from the LED through the light emitting surface. Thus, since the light emitted in the direction of the second cladding layer 23 is reflected on the metallic layer 5, the LED can be increased in light emitting efficiency and brightness.

An example of manufacturing method of the LED as shown in FIG. 3 will be described simply below.

First of all, an epitaxial wafer is manufactured by forming the compound semiconductor crystal layer 2 on a single crystal substrate. The compound semiconductor crystal layer 2 is formed by epitaxially growing the first cladding layer 21, the active layer and the second cladding layer 23 sequentially on the single crystal substrate. When the compound semiconductor crystal layer 2 is made of AlGaAs-based semiconductors or AlGaInP-based semiconductors, a GaAs substrate is typically used. When the compound semiconductor crystal layer 2 is made of AlGaInN-based semiconductors, a sapphire substrate or a GaN substrate is typically used as the single crystal substrate. As the epitaxial growth method, MOVPE (metalorganic vapor phase epitaxy) is typically used.

After the epitaxial growth, the transparent film 3 of silicon oxide, silicon nitride or the like is formed on the surface of the compound semiconductor crystal layer 2 of the epitaxial wafer. As a method of forming the transparent film 3, a heat CVD method or a plasma CVD method is typically used. After forming the transparent film 3, a partial ohmic electrode is formed by using a photolithographic method. The partial ohmic electrode 4 is formed of metallic layer(s) in single layer or multilayer. As a method of forming the partial ohmic electrode 4, a vacuum evaporation method or a sputtering method is mainly used.

The metallic layer 5 at the bonding portion is more generally formed in multilayer, a part of the metallic layer 5 is formed on the surface of the compound semiconductor crystal layer 2, and on the bonding portion-side surface of the conductive substrate 6, respectively. As the conductive substrate 6, Si is generally used which has good mechanical strength properties and high thermal conductivity. As the method of forming the metallic layer 5, the vacuum evaporation method or the sputtering method is mainly used.

After forming the metallic layer 5, the bonding process is implemented while the epitaxial wafer and the conductive substrate 6 are stacked such that the metallic layers thereof are in contact with each other. The bonding process is generally implemented such that, in vacuum or in inactivate gas, the epitaxial wafer and the conductive substrate 6 are heated and pressurized in the direction nearly perpendicular to the bonding interface.

For bonding the epitaxial wafer to the conductive substrate 6, a method using a low melting point metal as the metallic layer 5 and a method using intermetallic solid state bonding can be used.

In the method using the low melting point metal, the bonding process is implemented such that a comparatively low melting point alloy layer of Au—Sn or the like is formed on the epitaxial wafer-side bonding surface or on the conductive substrate 6—side bonding surface, and then heated to temperature higher than the melting point of the alloy. Temperature during the bonding process is generally 200° C. to 400° C.

In the method using the intermetallic solid state bonding, the bonding process is implemented such that a metallic layer of Au or the like is formed on the epitaxial wafer-side bonding surface and on the conductive substrate 6—side bonding surface. Temperature during the bonding process is generally 300° C. to 500° C.

After the bonding process, the single crystal substrate is removed to have a compound semiconductor wafer that the compound semiconductor crystal layer 2 and conductive substrate 6 are bonded through the metallic layer 5. The removing of the single crystal substrate is implemented by mechanical polishing, etching using an etchant, or the combination thereof. Then, the first electrode 1 and the second electrode 7 are formed on the compound semiconductor crystal layer 2—side surface and the conductive substrate 6—side surface, respectively, of the compound semiconductor wafer. Then, the compound semiconductor wafer is cut into chips by dicing. Thus, LEDs with a planar size of about 250 μm to 500 μm square are manufactured. In forming the first electrode 1 and the second layer 7, thermal treatment is implemented at about 400° C. in order to obtain the ohmic contact at low contact resistance.

[Omitted]

When the low melting point alloy is used as a bonding layer composing the metallic layer 5, air gaps occur at the bonding interface between the compound semiconductor crystal layer 2 and the conductive substrate 6, so that the fabrication yield of LEDs significantly decreases. It is assumed that the air gaps are caused by a part of the alloy layer altered into liquid phase during the thermal treatment for forming the first electrode 1 and the second electrode 7.

When the Au layer for the solid state bonding is used as the bonding layer composing the metallic layer 5, the occurrence of air gaps can be suppressed by forming the Au layer with a total thickness of about 2 μm. When the thickness of the Au layer is less than 2 μm, the air gaps increase. For example, when Si is used for the conductive substrate 6, it is estimated that, because of the difference in linear expansion coefficient from the epitaxial wafer, large stress occurs at the bonding interface and causes the occurrence of air gaps. When the Au layer is formed thicker, it is estimated that the Au layer can act as a stress relaxation layer and the occurrence of air gaps can be suppressed.

However, the vacuum evaporation method and the sputtering method as a method of forming the Au layer have a problem that the utilization efficiency of an Au material is extremely low at 5 to 25%, which cause an increase in manufacturing cost of the formation process of the Au layer. Here, the utilization efficiency of the material means the ratio between the weight of the metallic layer formed on the surface of the bonding portion and the weight of the material consumed by an apparatus for the vacuum evaporation or the sputtering method.

### SUMMARY OF THE INVENTION

Accordingly, it is an object of the invention to provide a semiconductor wafer and a light emitting diode that allow improvement in the utilization efficiency of a metallic material used for joining a compound semiconductor crystal layer and a conductive substrate when manufacturing the semiconductor wafer and the light emitting diode as well as manufacture thereof at lower cost. Also, it is another object of the invention to provide a manufacturing method of the light emitting diode.

In addition, it is another object of the invention is to provide a semiconductor wafer, the light emitting diode and manufacturing method thereof which is reliable to suppress a stress occurring at a bonding portion between a compound semiconductor crystal layer and conductive substrate.

(1) According to one embodiment of the invention, a compound semiconductor wafer comprises:

a compound semiconductor crystal layer; and

a conductive substrate bonded to the compound semiconductor crystal layer through a metallic layer,

wherein the metallic layer comprises a porous metallic microparticle layer comprising metallic microparticles comprising an average diameter of 1 nm to 100 nm and bonded to each other.

(2) According to another embodiment of the invention, a light emitting diode comprises:

a compound semiconductor crystal layer including an emission layer; and

a conductive substrate bonded to the compound semiconductor crystal layer through a metallic layer,

wherein the metallic layer comprises a first metallic layer formed on one principal surface of the compound semiconductor crystal layer, a second metallic layer formed on one principal surface of the conductive substrate, and a porous metallic microparticle layer formed between the first metallic layer and the second metallic layer, the porous metallic microparticle layer comprising metallic microparticles comprising an average diameter of 1 nm to 100 nm and bonded to each other.

(3) According to another embodiment of the invention, a method of manufacturing a light emitting diode that comprises a compound semiconductor crystal layer including an emission layer and a conductive substrate bonded to the compound semiconductor crystal layer through a metallic layer comprises:

epitaxially growing the compound semiconductor crystal layer on a single crystal substrate;

forming a first metallic layer on a surface of an uppermost layer of the compound semiconductor crystal layer;

forming a second metallic layer on a surface of the conductive substrate;

forming, on a surface of the first metallic layer and/or the second metallic layer, a metallic microparticle layer comprising metallic microparticles comprising an average diameter of 1 nm to 100 nm and bonded to each other;

bonding the first metallic layer on the single crystal substrate to the second metallic layer on the conductive substrate through the metallic microparticle layer; and

removing the single crystal substrate on the conductive substrate.

In the above embodiment (3), the following modifications and changes can be made.

(i) The forming of the metallic microparticle layer comprises,

applying a liquid form or a paste form material including the metallic microparticles,

heating the liquid form or the paste form material in order to evaporate an organic constituent included in the liquid form or the paste form material and to allow the metallic microparticles to be fusion-bonded to each other.

(ii) The bonding of the first metallic layer to the second metallic layer through the metallic microparticle layer is implemented in vacuum, and comprises pressurizing in a direction nearly perpendicular to a bonding interface therebetween and heating the single crystal substrate and the conductive substrate.

(iii) The applying of the liquid form or the paste form material is implemented by an ink-jet printing method or a screen printing method.

(iv) The metallic microparticles comprise a metallic microparticle selected from Cu, Ag, Au, Pd, Pt and Ru.

(v) The first metallic layer and the second metallic layer comprise a metallic layer composed primarily of a material selected from Cu, Ag, Au, Pd, Pt, and Ru.

In the above embodiment (1) or (2), the following modifications and changes can be made.

(vi) The porous metallic microparticle layer comprises a porosity of 70 to 95% sufficient to relax stress at a bonding interface between the compound semiconductor crystal layer and the conductive substrate. Herein, the “porosity” is defined as a ratio (percentage) of a measured specific gravity of metallic microparticles to specific gravity (i.e., 19.3 g/cm³ as a typical value) of gold. For example, the specific gravity of metallic microparticles can be calculated from measured weights of a Si chip before and after forming the metallic microparticle layer, and an average thickness of the metallic microparticle layer as well as a surface area of the chip. If the porosity is beyond 95%, it is not sufficient to relax the stress. If the porosity is below 70%, the concavity and convexity on the surface of the metallic microparticle layer enlarges so that the bonded wafer may be cracked during the bonding process of the compound semiconductor crystal layer and the conductive substrate (See FIG. 2(e)).

(vii) The porous metallic microparticle layer comprises a porosity so that a warpage of the compound semiconductor wafer with the porous metallic microparticle layer is suppressed less than 50% of a warpage of the compound semiconductor wafer without the porous metallic microparticle layer. Here, the “warpage” is defined as a difference between a maximum height and a thickness of a wafer. The LED compound semiconductor wafer (e.g., 4 inches in diameter) is convexly curved on the side of the conductive substrate (e.g., Si substrate), where a cross section thereof is shaped like an arc. The thickness of the wafer is measured by a contact type height gauge while the wafer is placed on a smooth and flat plate with the conductive substrate side down. On the other hand, the warpage of the wafer is measured as follows. First, the wafer is placed on the plate with the conductive substrate side up. Then, near the center of the wafer, a highest point from the surface of the plate is sought, and a height is measured at the highest point by the height gauge. Thus, as defined above, the warpage is calculated from the measured height and the thickness of the wafer. The warpage of conventional compound semiconductor wafers is about 60 micrometers on average. However, the warpage of the compound semiconductor wafers of the invention is reduced to less than 30 micrometers (i.e., 50% as compared to that of the conventional wafer) on average.

(viii) A thickness of the porous metallic microparticle layer is not less than 0.3 μm and less than 3 μm.

[Omitted]

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary cross-sectional view showing an LED in an embodiment according to the invention.

FIG. 2 is an exemplary cross-sectional view showing a manufacturing process of the LED in an embodiment according to the invention.

FIG. 3 is an exemplary cross-sectional view showing a conventional LED.

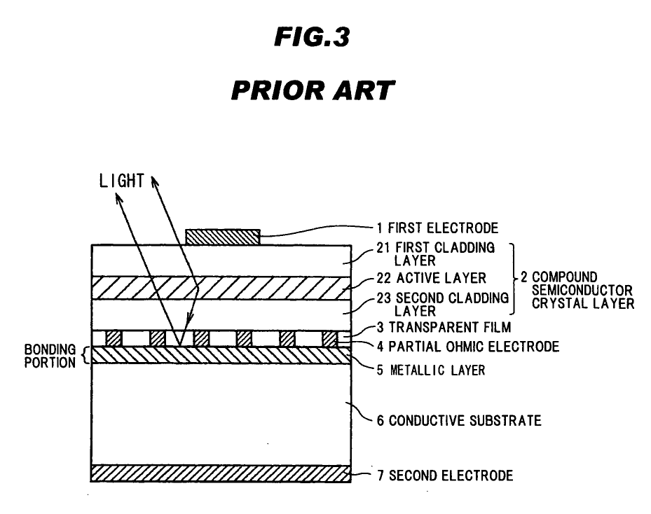

### DETAILED DESCRIPTION FOR PREFERRED EMBODIMENTS OF THE INVENTION

Hereinafter, an LED according to the embodiments of the invention will be described in detail with reference to the accompanying drawings.

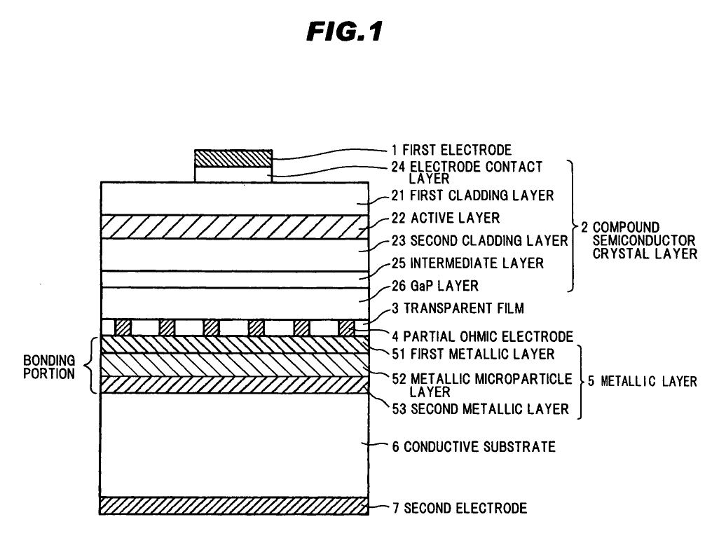

FIG. 1 is an exemplary cross-sectional view showing an LED (light emitting diode) in the embodiment according to the invention.

The LED has a structure that a compound semiconductor crystal layer 2 and a conductive substrate 6 are joined through a metallic layer 5. A first electrode 1 is formed on an upper surface of the compound semiconductor crystal layer 2, and a second electrode 7 is formed on a lower surface of the conductive substrate 6. The compound semiconductor crystal layer 2 comprises, on the first electrode 1 side, an electrode contact layer 24, a first cladding layer 21 consisting of AlGaInP, an emission layer portion comprising a active layer (emission layer) 22 and a second cladding layer 23, an intermediate layer 25, and a GaP layer 26. In addition, on the lower surface of the GaP layer 26, a layer comprising a transparent film 3, which is transparent to emitted light, and a partial ohmic electrode 4 are formed. The metallic layer 5 comprises a first metallic layer 51 which is formed on a surface of the layer comprising the transparent film 3 and the partial ohmic electrode 4, a second metallic layer 53 which is formed on a surface of the conductive substrate 6, and a metallic microparticle layer 52 which is formed as a bonding layer between the first metallic layer 51 and the second metallic layer 53.

The first metallic layer 51 and the second metallic layer 53 are typically composed of a multilayer, and generally can function as a bonding layer for bonding the compound semiconductor crystal layer 2 to the conductive substrate 6, as an adhesion layer for adhering the transparent film 3 to the partial ohmic electrode 4, as a light reflection layer for reflecting light emitted from the active layer 22, as a layer for suppressing the diffusion of constituent elements of the partial ohmic electrode 4 and the conductive substrate 6 into the interface of the bonding portion, and as a layer in ohmic contact with the conductive substrate 6.

The metallic microparticle layer 52 is a metallic layer which is formed by fusion bonding each other metallic microparticles with a diameter of nanometer level. The metallic microparticles are very active in chemical aspect so that they can be fusion-bonded simply by being partially contacted with each other in bare particle state. Therefore, when treating the metallic microparticles, it would be convenient to protect the surround of the metallic microparticles with an organic substance, then to disperse the metallic microparticles surrounded with the organic substance in an organic solvent, so as to treat the metallic microparticles in the form of a liquid or paste. The viscosity of solution in which the metallic microparticles are dispersed can be controlled by changing the concentration of the metallic microparticles, the kind of the organic protective substance or organic solvent surrounding the metallic microparticles.

The metallic microparticles with an average diameter of 1 nm to 100 nm are used. When the average diameter of the metallic microparticles ranges from 1 nm to 100 nm, the resistivity of the metallic microparticle layer is at the same level as that of a metallic layer formed by the vacuum evaporation method or the sputtering method. If the average diameter of the metallic microparticles is larger than 100 nm, the resistivity of the metallic microparticle layer increases by one digit or more. In contrast, if the average diameter of the metallic microparticles is smaller than 1 nm, the measurement accuracy of the average diameter deteriorates, so that the average diameter becomes difficult to control. Herein, the average diameter of metallic microparticles is measured by a particle size measuring apparatus using the dynamic light scattering method. “average diameter” is defined as a particle diameter that corresponds to 50% of cumulative frequency in cumulative frequency distribution for particle size by volumetric basis. A commercially available example of the particle size measuring apparatus is UPA-EX150 manufactured by Nikkiso Co., Ltd.

It is more preferable to use metallic particles with an average diameter of 1 nm to nm. In bonding the compound semiconductor crystal layer 2 to the conductive substrate 6, the surface of the metallic microparticle layer 52 is desirably flat and smooth so as to prevent the occurrence of void at the bonding interface. By using the metallic particles with an average diameter of 1 nm to 30 nm, the surface of the manufactured metallic microparticle layer 52 can be made very flat and smooth, where its surface roughness/center-line average (Ra) is measured less than 9 nm by SPM (Scanning Probe Microscope). If the average diameter is beyond 30 nm, Ra tends to increase. However, no void is observed at the bonding interface in the range less than 100 nm in average diameter.

A material for the metallic microparticle layer 52, the first metallic layer 51, and the second metallic layer 53 is preferably selected from Cu, Ag, Au, Pd, Pt and Ru. Among these materials, considering the operation reliability and cost of the LED, Au is the most promising material.

Although Ag is less expensive than Au, Ag tends to cause electromigration that may decrease the reliability for the LED. It is known that water is involved in the electromigration of Ag. Thus, if the LED is mounted in a waterproof package such as a metallic seal adapted for preventing the invasion of water, Ag may be used.

Cu is a material easy to be oxidized in the air. By deoxidizing Cu in reduction atmosphere during the process of forming the metallic microparticle layer 52 and the bonding process, Cu can be used.

Pd, Pt and Ru are a metallic material hard to be oxidized like Au, and can be therefore applied to bonding through the metallic microparticle layer 52.

In forming the metallic microparticle layer 52, at first, the liquid or paste metallic microparticles is applied to the surface of the first metallic layer 51 and/or the surface of the second metallic layer 53. Then, the metallic microparticle layer 52 is formed by heating to evaporate the organic constituent and to fusion bond the metallic microparticles.

In order to apply the liquid or paste metallic microparticles thereto, the ink jet printing method (spray method) or a screen printing method is used. By applying the liquid or paste metallic microparticles by the ink jet printing method or the screen printing method, utilization efficiency of the metallic material can be increased by more than 90%.

After forming the metallic microparticle layer 52, an epitaxial wafer with the compound semiconductor crystal layer 2 epitaxially grown on a single crystal substrate as GaAs etc. is stacked in vacuum on the conductive substrate 6. Then, the epitaxial wafer and the conductive substrate 6 are pressurized and heated in the direction nearly perpendicular to the bonding interface therebetween so as to perform the bonding process.

After the bonding process, the single crystal substrate used for the epitaxial growth is removed. Thus, a compound semiconductor wafer for LEDs can be obtained which comprises the compound semiconductor crystal layer 2 and the conductive substrate 6 that are bonded through the metallic layer 5 including the metallic microparticle layer 52.

Then, warpage of the compound semiconductor wafer for LEDs is measured where the wafer has a diameter of 4 inches and the metallic microparticle layer 52 as the bonding layer. As a result, it is proved that the warpage is suppressed less than 50% of that of a compound semiconductor wafer bonded through only a metallic layer (i.e., without the metallic microparticle layer 52) formed by the vacuum evaporation method or sputtering method. It is assumed that the metallic microparticle layer 52 is essentially porous as compared with the metallic layer formed by the vacuum evaporation method or sputtering method, so that the porous metallic microparticle layer 52 effectively functions to relax stress at the bonding interface.

Then, the first electrode 1 and the second electrode 7 are formed on the surface of the compound semiconductor crystal layer 2 and the conductive substrate 6, respectively, of the compound semiconductor wafer. Then, the wafer is cut into chips by dicing to produce LEDs (bare chips).

The LED of this embodiment is high in emission output and reliability, so that it can be applied to a traffic light, an automobile exterior light, a backlight module for liquid crystal display, or the like.

Although in the above embodiment the LED is explained, it is needless to say that the invention can be applied to a compound semiconductor wafer for a device other than the LED which is formed by bonding a compound semiconductor crystal layer and a conductive substrate through a metallic layer.

### EXAMPLES

Examples according to the invention will be explained below.

### Example 1

In Example 1, an LED which has the same cross-sectional structure as the LED in the embodiment indicated in FIG. 1 is manufactured. That is to say, as shown in FIG. 1, the compound semiconductor crystal layer 2 is bonded to the conductive substrate 6 through the metallic layer 5, and the first electrode 1 and the second electrode 7 for power distribution to the LED are formed on the surface of the compound semiconductor crystal layer 2 and the conductive substrate 6, respectively.

In Example 1, the compound semiconductor crystal layer 2 comprises the electrode contact layer 24, the first cladding layer 21, the active layer 22, the second cladding layer 23, the intermediate layer 25, and the GaP layer 26.

The electrode contact layer 24 is made of Te doped n-type (AlₓGa₁₋ₓ)_{y}In_{1-y}P (x≈0, y≈0.51), its dopant concentration is 2×10¹⁸ cm⁻³, and its thickness is 0.3 μm.

The first cladding layer 21 is made of Te doped n-type (AlₓGa₁₋ₓ)_{y}In_{1-y}P (x≈0.7, y≈0.51), its dopant concentration is about 1×10¹⁷ cm⁻³, and its thickness is about 2 μm.

The active layer 22 is made of (AlₓGa₁₋ₓ)_{y}In_{1-y}P and has a multiquantum well structure. In Example 1, the multiquantum well structure is composed of layers made of (AlₓGa₁₋ₓ)_{y}In_{1-y}P (x≈0.5, y≈0.51) and (AlₓGa₁₋ₓ)_{y}In_{1-y}P (x≈0, y≈0.51) and adapted to have a peak wavelength in LED emission energy spectrum of about 635 nm. The layers composing the multiquantum well structure are undoped.

The second cladding layer 23 is made of Mg doped p-type (AlₓGa₁₋ₓ)_{y}In_{1-y}P (x≈0.7, y≈0.51), its dopant concentration is about 4×10¹⁷ cm⁻³, and its thickness is about 0.5 μm.

The intermediate layer 25 is made of Mg doped p-type (AlₓGa₁₋ₓ)_{y}In_{1-y}P (x≈0, y≈0.7), its dopant concentration is about 5×10¹⁸ cm⁻³, and its thickness is about 20 nm.

The GaP layer 26 has p-type conductivity (Mg-doped), its dopant concentration is about 4.5×10¹⁸ cm⁻³, and its thickness is about 1 m.

The first electrode 1 is formed on the surface of the electrode contact layer 24, and the electrode contact layer 24 is removed by etching except the area under the first electrode 1. This prevents the lowering of the light extraction efficiency due to the electrode contact layer 24 which has light absorption property.

At the bottom of the GaP layer 26, a layer composed of the transparent film 3 transparent to emitted light and the partial ohmic electrode 4 is formed. The transparent film 3 is, in Example 1, formed of a silicon oxide membrane. The partial ohmic electrode is in ohmic contact with the p-type GaP layer 26 and further connected to the metallic layer 5 (51).

The metallic layer 5 is composed of the first metallic layer 51, the metallic microparticle layer 52, and the second metallic layer 53. Both the first metallic layer 51 and the second metallic layer 53 have a metallic layer of Au at the surface of which they contact the metallic microparticle layer 52, and the Au layer is 0.1 μm in thickness.

The metallic microparticle layer 52 is formed by fusion bonding Au microparticles with an average diameter of 8 nm. In Example 1, the metallic microparticle layer 52 is formed on the surface of the second metallic layer 53, and its thickness is 1.8 μm.

As the conductive substrate 6, in Example 1, n-type single crystal Si is used. On the opposite side to the bonding side of the conductive substrate 6, the second electrode 7 is formed, and the second electrode 7 is in ohmic contact with the conductive substrate 6.

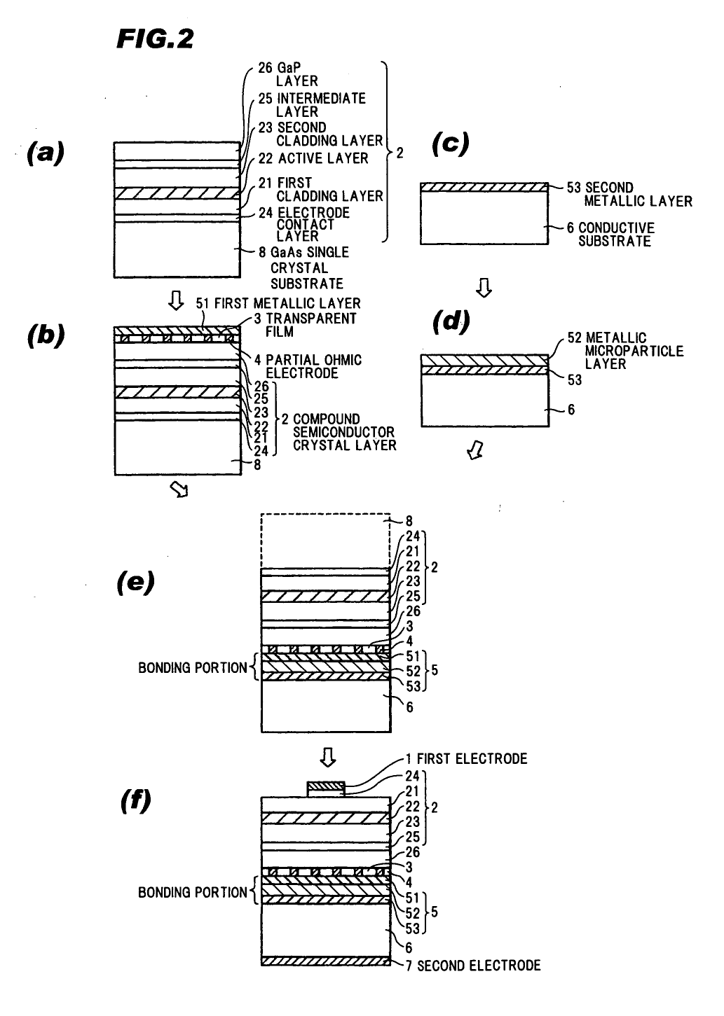

A manufacturing method of the LED in FIG. 1 of the embodiment will be described below with reference to FIG. 2.

First, on a GaAs single crystal substrate 8, the compound semiconductor crystal layer 2 is formed by epitaxially growing an electrode contact layer 24, a first cladding layer 21, an active layer 22, a second cladding layer 23, an intermediate layer 25, and a GaP layer 26 in this order, so as to have an epitaxial wafer (FIG. 2 (a)). As the epitaxial growth method, MOVPE method is used.

In the MOVPE method, as a source material for group III element used in the epitaxial growth of the compound semiconductor crystal layer 2, organic metallic materials such as trimethyl gallium (TMG), trimethyl aluminum (TMA) and trimethyl indium (TMI) are used. As a material for group V element, hydride gas such as phosphine (PH₃) is used.

The organic metallic materials and the hydride gas described above are supplied into a reaction chamber of the MOVPE apparatus along with carrier gas such as hydrogen gas. The reaction chamber is provided with a susceptor and a heating mechanism, the GaAs single crystal substrate 8 is placed at a predetermined position of the susceptor, and then heated by the heating mechanism such as a heater. In Example 1, the epitaxial growth is implemented on the GaAs single crystal substrate 8 at 600° C. to 750° C.

As a dopant element for allowing the compound semiconductor crystal layer 2 to have p-type conductivity, Mg is used. Bis-cyclopentadienyl magnesium (Cp₂Mg) is used as an Mg material. As a dopant element for allowing the compound semiconductor crystal layer 2 to have n-type conductivity, Te is used. Dimethyl tellurium (DMTe) and diethyl tellurium (DETe) are used as a Te material. The dopant materials are concurrently supplied into the reaction chamber along with the group III element and group V element materials.

After manufacturing the epitaxial wafer, on the surface of the compound semiconductor crystal layer 2, the silicon oxide membrane is formed as the transparent film by plasma CVD method, In addition, by a lift off method using photolithography, the partial ohmic electrode 4 is formed dispersed at a part of the transparent film 3. The partial ohmic electrode 4 has a stacking structure composed of an AuZn layer, a Ni layer, and an Au layer, these metallic layers being formed by vacuum evaporation.

After forming the partial ohmic electrode 4, on the layer comprising the transparent layer 3 and the partial ohmic electrode 4, the first metallic layer 51 is formed by the vacuum evaporation method (FIG. 2 (b)). The first metallic layer 51 is provided with a 0.1 μm thick Au layer as a top layer thereof.

For the conductive substrate 6, in Example 1, a P-doped n-type Si substrate with a carrier concentration of about 1×10¹⁸ cm⁻³ is used. On the surface of the conductive substrate 6, the second metallic layer 53 is formed by the vacuum evaporation method (FIG. 2 (c)). The second metallic layer 53 is provided with a 0.1 μm thick Au layer as a top layer thereof.

After the second metallic layer 53 is formed on the surface of the conductive substrate 6, the metallic microparticle layer 52 is formed on the surface of the second metallic layer 53 (FIG. 2 (d)). The metallic microparticle layer 52 is formed by fusion bonding Au microparticles with an average diameter of about 8 nm. First, a liquid material is prepared in which Au microparticles protected by surrounding organic substance are dispersed in organic solvent. Then, the liquid material is film-coated on the surface of the second metallic layer 53 by screen printing method. Then, the metallic microparticle layer 52 is formed by heating to evaporate the organic solvent and the organic substance surrounding the Au microparticles, to fusion bond the Au microparticles each other to be integrated substantially.

The heating is, in Example 1, conducted by using a hot plate on two temperature stages at about 150° C. and at about 300° C. On the first stage at about 150° C., most part of the organic substance included in the coated liquid material is evaporated. On the second stage at about 300° C., the remaining organic substance is evaporated while allowing the fusion bonding of the Au microparticles. The composition of the Au microparticles included in the liquid material is about 60% by weight.

In Example 1, the thickness of the metallic microparticle layer 52 is measured about 1.8 μm. The thickness of the metallic microparticle layer 52 is measured by observing a cut surface of the compound semiconductor wafer described later. In Example 1 as shown in FIG. 1, 2 μm is given by summing the thickness of Au layer included in the metallic microparticle layer 52, and the thickness of the Au layers each provided for the first metallic layer 51 and the second metallic layer 53 that are both in contact with the metallic microparticle layer 52.

After forming the metallic microparticle layer 52, the Au layer at the surface of the first metallic layer 51 of the epitaxial wafer and the surface of the metallic microparticle layer 52 of the conductive substrate 6 are stacked in vacuum. Then, the epitaxial wafer and the conductive substrate 6 are both pressurized in a direction nearly perpendicular to the bonding interface therebetween while being heated to conduct the bonding thereof (FIG. 2 (e)). In Example 1, the bonding is implemented in vacuum less than 15 Pa.

Meanwhile, the pressurizing is implemented such that two plate-like jigs are set parallel as one above the other, the stacked epitaxial wafer and the metallic microparticle layer 52 are set between the jigs, and the upper jig is pressed down with the lower jig fixed. A pressure of the pressurizing, in Example 1, is about 0.5 MPa.

The heating is conducted by two heaters, one being set over the upper jig and the other being set below the lower jig, to heat the epitaxial wafer and the conductive substrate through the jigs. In Example 1, temperature of the heating is at about 350° C.

After the bonding, the GaAs single crystal substrate 8 used for the epitaxial growth is removed so that the compound semiconductor wafer composed of the compound semiconductor crystal layer 2 and the conductive substrate 6 bonded through the metallic microparticle layer 52 is formed (FIG. 2 (e)).

The removing of the GaAs single crystal substrate 8 is implemented by mechanically polishing a part of the GaAs single crystal substrate 8 and then by etching the GaAs single crystal substrate 8 using an etchant.

After manufacturing the compound semiconductor wafer, a part of the electrode contact layer 24 is removed by photolithography. Then, the first electrode 1 is formed on the surface of the electrode contact layer 24 by liftoff utilizing photolithography. The first electrode 1 has a stacking structure composed of an AuGe layer, a Ni layer and an Au layer, these metallic layers being formed by the vacuum evaporation.

After forming the first electrode 1, the second electrode 7 is formed on the conductive substrate 6—side surface of the compound semiconductor wafer. After forming the first electrode 1 and the second electrode 7, heating is implemented at 400° C. The heating is implemented to obtain low resistive ohmic contact between the first electrode 1 and the electrode contact layer 24, and between the second electrode 7 and the conductive substrate 6.

After the heating, the compound semiconductor wafer is cut into chips by dicing to have LEDs with a planar size of about 300 μm×300 μm (FIG. 2 (f)).

Mounting the manufactured LED on a metallic stem, measurements of emission power, forward voltage and reliability tests are implemented.

The measurements of emission power and forward voltage are implemented under the conditions that current density is about 22.2 A/cm² and ambient temperature is 25° C. By the LED of Example 1, good values are obtained about 7 mW in emission power and about 1.95V in forward voltage.

These characteristic values are the same as obtained by an LED (Comparison Example) manufactured by bonding through an Au layer (with a thickness of 1.8 μm) formed by the vacuum evaporation method instead of the metallic microparticle layer 52.

The reliability test is implemented by (1) continuous current test for 2000 hours at current density of 22.2 A/cm² and at ambient temperature of 85° C. and humidity of 85%, (2) shelf test for 2000 hours at ambient temperature of 85° C. and humidity of 85%, and (3) thermal shock test at −55° C. to 100° C. By the LED of Example 1, good results are obtained a fluctuation in emission power of less than 2%, and no fluctuation in forward voltage after the reliability test.

On the other hand, as the results of the reliability test for LED (Comparison Example) manufactured by bonding through an Au layer (with a thickness of 1.8 μm) formed by the vacuum evaporation method instead of the metallic microparticle layer 52, emission power decreases by about 7% after the thermal shock test. It is assumed that the decrease in emission power in Comparison Example after the thermal shock test is caused by stress due to the difference in linear expansion coefficient between the compound semiconductor crystal layer 2 and the conductive substrate 6, and that the metallic microparticle layer 52 in Example 1 can relax the stress.

Although in Example 1 the thickness of the metallic microparticle layer 52 is 1.8 μm, the same good results as Example 1 are obtained for examples with a thickness of not less than 0.3 μm and less than 3 μm in the metallic microparticle layer 52. When the thickness of the metallic microparticle layer 52 is less than 0.3 μm or more than 3 μm, air gaps at the bonding interface between the metallic microparticle layer 52 and the first metallic layer 51 tend to increase.

The air gaps at the bonding interface are evaluated by ultrasonic tester. It is assumed that the increase of the air gaps is caused by a decrease in stress relaxation function of the metallic microparticle layer 52 when the thickness of the metallic microparticle layer 52 is less than 0.3 μm. On the other hand, it is assumed that the increase of the air gaps is caused by an increase in organic constituent remaining in the metallic microparticle layer 52 when the thickness of the metallic microparticle layer 52 is more than 3 μm.

Although in Example 1 the pressure for bonding the epitaxial wafer to the conductive substrate 6 is about 0.5 MPa, the same good results as Example 1 are obtained for examples at a pressure of 0.1 MPa to 10 MPa. When the pressure is less than 0.1 MPa, air gaps tend to increase at the bonding interface between the metallic microparticle layer 52 and the first metallic layer 51. On the other hand, when the pressure is more than 10 MPa, breaking of the epitaxial wafer occurs frequently, so that fabrication yield of the compound semiconductor wafer deteriorates.

Although in Example 1 the temperature during the bonding process is about 350° C., the same good results as Example 1 are obtained for examples at a temperature of 290° C. to 450° C. When the temperature is lower than 290° C., air-gaps tend to drastically increase at the bonding interface between the metallic microparticle layer 52 and the first metallic layer 51. On the other hand, when the temperature is higher than 450° C., forward voltage of the manufactured LED tends to increase. It is assumed that the increase in forward voltage is mainly caused by an increase in contact resistance between the partial ohmic electrode 4 and the GaP layer 26.

In Example 1, by coating the liquid material including the Au microparticles on the surface of the second metallic layer 53 by the screen printing method, utilization efficiency of the Au material can be increased to about 92%. In case of using the Au layer (Comparison Example) formed by the vacuum evaporation method instead of the metallic microparticle layer 52, utilization efficiency of the Au material is about 12%.

Meanwhile, the method of coating the liquid material including the Au microparticles is not limited to the screen printing method, and when using the ink jet printing method in order to coat the liquid material including the Au microparticles, utilization efficiency of the Au material can be also increased more than about 90%. Further, when using a roll coating method in order to coat the liquid material including the Au microparticles, utilization efficiency of the Au material can be also more than about 50%.

Although in Example 1 the liquid material including the Au microparticles is coated on the surface of the second metallic layer 53, the liquid Au microparticles may be coated on the surface of only the first metallic layer 51 or both the first metallic layer 51 and the second metallic layer 53.

When the metallic microparticle layer 52 is formed by the heating after coating the liquid material including the Au microparticles, the hot plate (for heating the jigs) is used. However, other heating devices such as an infrared irradiator can be used. For example, a substrate coated with the liquid material including the Au microparticles can be conveyed through inside of a cylindrical heater at temperature distribution of about 100° C. to 500° C. in the longitudinal direction, so that the evaporation of the organic constituent and the fusion bonding of the Au microparticles can be implemented.

### Example 2

In Example 2, a metallic microparticle layer is applied to a metallic layer 5 of a bonding portion as in the LED (Example 1) as shown in FIG. 1, and further applied to the first electrode 1 (alternatively, the metallic microparticle layer may be applied only to the first electrode 1).

In Example 2, the first electrode 1 is composed of an AuGe layer, a Ni layer and an Au layer formed in this order from the electrode contact layer 24. The Au layer comprises an Au layer formed by the vacuum evaporation method and an Au microparticle layer. The thickness of the Au layer formed by the vacuum evaporation method is about 0.05 μm, and the thickness of the Au microparticle layer is about 0.5 μm.

The manufacturing method of the LED according to Example 2 is nearly the same as used in the LED of Example 1. However, the Au microparticle layer is formed on the first electrode 1, which is composed of the AuGe layer, the Ni layer and the Au layer, formed by the vacuum evaporation method after forming the second electrode 7. The AuGe layer, the Ni layer and the Au layer formed by the vacuum evaporation method are circularly formed in plane view with a diameter of about 100 μm by the liftoff method using the photolithography. Then the Au microparticle layer is formed thereon nearly in the same shape as the first electrode 1 by the screen printing method.

During the screen printing, the liquid material including the Au microparticles with an average diameter of about 5 nm is coated on the Au layer formed by the vacuum evaporation method. The evaporating of the organic constituent from the liquid material including the Au microparticles and the fusion bonding of the Au microparticles are implemented by heating process at 400° C. in order to obtain a low resistive ohmic contact between the first electrode 1 and the electrode contact layer 24, as well as between the second electrode 7 and the conductive substrate 6.

The first electrode 1 of the LED according to Example 2 is connected to a power supplying terminal of a metallic stem on which the LED is mounted by wire bonding of an Au wire with a diameter of about 22 μm, and then the tensile test of the Au wire is implemented. As a result, it is confirmed that all of fracturing points are on the Au wire and that the Au microparticle layer as the uppermost surface of the first electrode 1 is connected with the Au wire strongly.

When the connection of the Au microparticle layer as the uppermost surface of the first electrode 1 and the Au wire through the wire bonding is implemented, a thickness of 0.3 μm to 1 μm is required as the thickness of the Au layer, in order to prevent the destruction of a base layer by a connection weight in the wire bonding and to ensure adequate strength of the Au layer. In general, the upper side electrode of the LED such as the first electrode 1 is circularly formed in plane view with a diameter of about 100 μm. As a result, when using the vacuum evaporation method as a method for forming the Au layer as the upper electrode of an LED with a planar size of about 300 μm×300 μm, utilization efficiency of the Au material decreases to about 1 to 2%. Therefore, by forming the most part of the Au layer with the Au metallic particles by the screen printing method, the utilization efficiency of the Au material can be increased to large degree.

Although in Example 2 the screen printing method is used as a method of the Au microparticle layer, the method is not limited to the screen printing method. For example, the ink jet printing method can be used.

Although in Example 2 Au is used as a material of the metallic microparticle layer formed on the uppermost surface of the first electrode 1, the material is not limited to Au. Ag, Pd, Pt, Ru, Cu, or alloy thereof may be used.

### Modified Example

Instead of the Au microparticles of 8 nm in average diameter, Ag microparticles of nm in average diameter are used. The pressure during the bonding process is about 0.7 MPa. In this example, after the manufactured LED is mounted on the metallic stem, a metal cap with a glass window for extracting light therethrough is attached to the metallic stem so as to prevent water from penetrating at the periphery of the LED. The other conditions of the manufacturing process are the same as in Example 1. As a result, the LED of this example can have the same properties and performances as that of Examples 1 to 2.

It should be noted that the present invention is not limited to the embodiment described above, and the various combinations and changes may be made without departing from or changing the technical idea of the present invention.

What is claimed is:

1. A compound semiconductor wafer, comprising:
a compound semiconductor crystal layer; and
a conductive substrate bonded to the compound semiconductor crystal layer through a metallic layer,
wherein the metallic layer comprises a porous metallic microparticle layer comprising metallic microparticles comprising an average diameter of 1 nm to 100 nm and bonded to each other.

2. A light emitting diode, comprising:
a compound semiconductor crystal layer including an emission layer; and
a conductive substrate bonded to the compound semiconductor crystal layer through a metallic layer,
wherein the metallic layer comprises a first metallic layer formed on one principal surface of the compound semiconductor crystal layer, a second metallic layer formed on one principal surface of the conductive substrate, and a porous metallic microparticle layer formed between the first metallic layer and the second metallic layer, the porous metallic microparticle layer comprising metallic microparticles comprising an average diameter of 1 nm to 100 nm and bonded to each other.

3. A method of manufacturing a light emitting diode that comprises a compound semiconductor crystal layer including an emission layer and a conductive substrate bonded to the compound semiconductor crystal layer through a metallic layer, comprising:
epitaxially growing the compound semiconductor crystal layer on a single crystal substrate;
forming a first metallic layer on a surface of an uppermost layer of the compound semiconductor crystal layer;
forming a second metallic layer on a surface of the conductive substrate;
forming, on a surface of the first metallic layer and/or the second metallic layer, a metallic microparticle layer comprising metallic microparticles comprising an average diameter of 1 nm to 100 nm and bonded to each other;
bonding the first metallic layer on the single crystal substrate to the second metallic layer on the conductive substrate through the metallic microparticle layer; and
removing the single crystal substrate on the conductive substrate.

4. The method according to claim 3, wherein:
the forming of the metallic microparticle layer comprises,
applying a liquid form or a paste form material including the metallic microparticles,
heating the liquid form or the paste form material in order to evaporate an organic constituent included in the liquid form or the paste form material and to allow the metallic microparticles to be fusion-bonded to each other.

5. The method according to claim 3, wherein:
the bonding of the first metallic layer to the second metallic layer through the metallic microparticle layer is implemented in vacuum, and comprises pressurizing in a direction nearly perpendicular to a bonding interface therebetween and heating the single crystal substrate and the conductive substrate.

6. The method according to claim 4, wherein:
the applying of the liquid form or the paste form material is implemented by an ink-jet printing method or a screen printing method.

7. The method according to claim 3, wherein:
the metallic microparticles comprise a metallic microparticle selected from Cu, Ag, Au, Pd, Pt and Ru.

8. The method according to claim 3, wherein:
the first metallic layer and the second metallic layer comprise a metallic layer composed primarily of a material selected from Cu, Ag, Au, Pd, Pt, and Ru.

9. The compound semiconductor wafer according to claim 1, wherein:
the porous metallic microparticle layer comprises a porosity of 70 to 95% sufficient to relax stress at a bonding interface between the compound semiconductor crystal layer and the conductive substrate.

10. The compound semiconductor wafer according to claim 1, wherein:
the porous metallic microparticle layer comprises a porosity so that a warpage of the compound semiconductor wafer with the porous metallic microparticle layer is suppressed less than 50% of a warpage of the compound semiconductor wafer without the porous metallic microparticle layer.

11. The compound semiconductor wafer according to claim 1, wherein:
a thickness of the porous metallic microparticle layer is not less than 0.3 μm and less than 3 μm.

12. The light emitting diode according to claim 2, wherein:
the porous metallic microparticle layer comprises a porosity of 70 to 95% sufficient to relax stress at a bonding interface between the compound semiconductor crystal layer and the conductive substrate.

13. The light emitting diode according to claim 2, wherein:
a thickness of the porous metallic microparticle layer is not less than 0.3 μm and less than 3 μm.
